(19) United States
(12) Patent Application Publication
(10) Pub. No.: US 2021/0287929 A1
(43) Pub. Date: Sep. 16, 2021

(54) HEATER UNIFORMITY IN SUBSTRATE SUPPORTS

(71) Applicant: Applied Materials, Inc., Santa Clara, CA (US)

(72) Inventor: Vijay D. Parkhe, Santa Clara, CA (US)

(73) Assignee: Applied Materials, Inc., Santa Clara, CA (US)

(21) Appl. No.: 16/820,225

(22) Filed: Mar. 16, 2020

(51) Int. Cl. H01L 21/687; H01L 21/67

(52) U.S. Cl. CPC H01L 21/68757; H01L 21/67103

(57) ABSTRACT

Exemplary semiconductor substrate supports may include a platen configured to support a semiconductor substrate. The substrate supports may include a stem coupled with the platen. The substrate supports may include a heater embedded within the platen. The heater may include a metal wire and a barrier layer extending about the metal wire.

### TECHNICAL FIELD

The present technology relates to semiconductor methods and equipment. More specifically, the present technology relates to substrate support assemblies and methods of forming substrate support assemblies.

### BACKGROUND

Many substrate processing systems include substrate supports, such as an electrostatic chuck in combination with a base, to retain a wafer during semiconductor substrate processing. The substrate support may include a number of layers of materials or plates coupled together. The plates may perform separate functions, such as operating as an electrode, operating as a heater, operating to cool, among other aspects of semiconductor processing. As temperature uniformity of a substrate during processing may contribute greater impact on semiconductor processing, uniformity of heating elements and consistently incorporating those elements within a substrate support is becoming more important. Because heating elements may be included within molds during formation processes, controlling the heater elements during formation may be challenged.

Thus, there is a need for improved systems and methods that can be used to improve formation and performance of processing chambers and components. These and other needs are addressed by the present technology.

### SUMMARY

Exemplary semiconductor substrate supports may include a platen configured to support a semiconductor substrate. The substrate supports may include a stem coupled with the platen. The substrate supports may include a heater embedded within the platen. The heater may include a metal wire and a barrier layer extending about the metal wire.

In some embodiments, the platen may be or include a ceramic. The metal wire may be or include molybdenum or tungsten. The barrier layer may be or include a nitride or oxide. The barrier layer may be or include ruthenium, rhenium, or aluminum. The metal wire may be characterized by a thickness of less than or about 0.5 mm. The barrier layer may be characterized by a thickness of less than or about 10 μm.

Some embodiments of the present technology may encompass methods of forming a semiconductor substrate support. The methods may include positioning a first body within a mold. The methods may include disposing a heater on the first body within the mold. The heater may include a metal wire and a barrier layer extending about the metal wire. The methods may include positioning a second body within the mold overlying the first body and the heater. The methods may include forming a monolith body of the first body and the second body. The monolith body may include a platen for a semiconductor substrate support.

In some embodiments, forming the monolith body may include sintering the first body and the second body at a temperature greater than or about 1500° C. The barrier layer may be or include a nitride or oxide. The barrier layer may be or include ruthenium, rhenium, or aluminum. The barrier layer may prevent interaction between the metal wire and the first body or the second body. The metal wire may be characterized by a thickness of less than or about 0.3 mm. The barrier layer may be characterized by a thickness of less than or about 5 μm. The platen may be or include a ceramic. The ceramic may be or include aluminum oxide or aluminum nitride. The metal wire may be or include molybdenum or tungsten.

Some embodiments of the present technology may encompass methods of forming a semiconductor substrate support. The methods may include positioning a first ceramic body within a mold. The methods may include disposing a heater on the first ceramic body within the mold. The heater may include a molybdenum or tungsten wire and an oxide or nitride barrier layer extending about the molybdenum or tungsten wire. The methods may include positioning a second ceramic body within the mold overlying the first ceramic body and the heater. The methods may include sintering the first ceramic body and the second ceramic body to form a monolith body platen of a semiconductor substrate support.

In some embodiments, forming the monolith body platen may include sintering the first ceramic body and the second ceramic body at a temperature greater than or about 1700° C. The molybdenum or tungsten wire may be characterized by a thickness of less than or about 0.3 mm, and the oxide or nitride barrier layer may be characterized by a thickness of less than or about 5 μm.

Such technology may provide numerous benefits over conventional systems and techniques. For example, coated heater wires may be protected from interaction with materials during the substrate support formation process. Additionally, by maintaining uniform properties across the heater wire, temperature uniformity may be improved throughout the substrate support. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing system according to some embodiments of the present technology.

FIG. 2 shows a schematic partial cross-sectional view of an exemplary substrate support according to some embodiments of the present technology.

FIG. 3 shows selected operations in a method of processing a semiconductor substrate according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Semiconductor processing includes a number of formation and removal operations performed to produce intricate structures on a substrate. As feature sizes continue to reduce, and processing effects produce greater impact on materials formed or removed, improved control over processing aspects may become more beneficial. For example, many processing operations may be temperature sensitive, and different deposition or etch amounts as well as different material properties may be caused by a lack of uniformity of temperature across a semiconductor substrate.

To control temperatures of the substrate for processing, many substrate supports may have multiple features to provide increased control and manipulation of temperature. For example, many substrate supports include one or more heating elements within the support structure for heating a substrate being supported during processing. Heating elements may include fluids flowed through the substrate support, and may include metal filaments disposed within the substrate support and operated as resistive heaters. When metal filaments are incorporated in ceramic or dielectric material, they are often incorporated between layers during the sintering process. For example, a metal wire may be included between green bodies or powders and then incorporated in the final product after sintering. An issue that occurs in conventional technology is that the metal wire can react with aspects of the green bodies or powders, which can impact resistivity of the wire. This can create hot and cold spots on the substrate support and the substrate, which can impact the process being performed.

The present technology overcomes these issues by incorporating a barrier layer about the metal wire of the heater. The material applied may be selected specifically to withstand the sintering process, and coat the filament completely to prevent reaction or interaction between the heater wire and the ceramic materials.

Although the remaining disclosure will routinely identify specific processes and chambers utilizing the disclosed technology, it will be readily understood that the systems and methods are equally applicable to a variety of other chambers in which semiconductor processing may occur. Accordingly, the technology should not be considered to be so limited as for use in specific chambers or processes alone. The disclosure will discuss one possible system and chamber that can be used with the present technology before describing systems and methods or operations of exemplary process sequences according to some embodiments of the present technology. It is to be understood that the technology is not limited to the equipment described, and processes discussed may be performed in any number of processing chambers and systems.

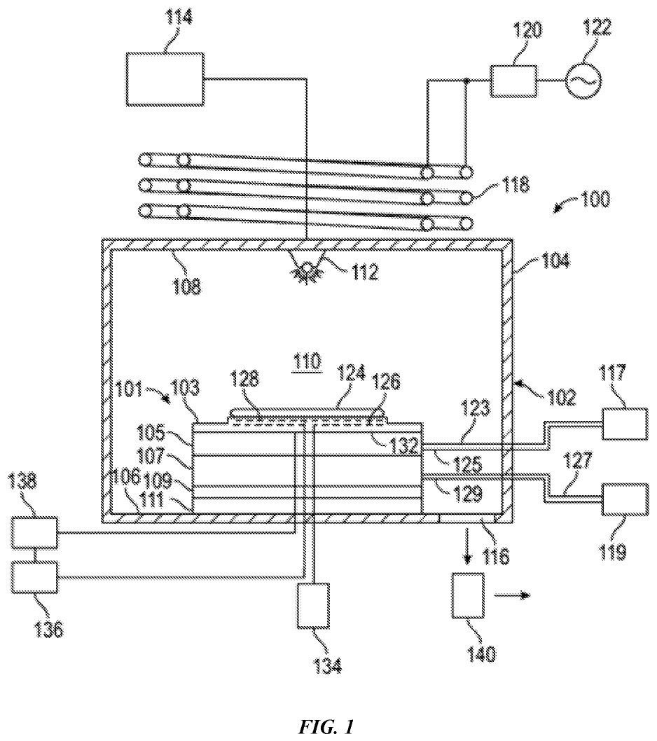

FIG. 1 illustrates a cross-sectional schematic view of an exemplary plasma processing chamber 100, shown configured as an etch chamber, having a substrate support assembly 101. The substrate support assembly 101 may be utilized in other types of plasma processing chambers, for example plasma treatment chambers, annealing chambers, physical vapor deposition chambers, chemical vapor deposition chambers, and ion implantation chambers, among others, as well as other systems that may uniformly maintain a surface or substrate, such as a substrate 124, at a particular temperature. In some embodiments chamber 100 may be configured for cryogenic processing, although any other processing conditions may similarly be encompassed. Reactive ion etching a substrate maintained at a cryogenic temperature may improve anisotropic aspects of the etch process as explained above, for example.

The plasma processing chamber 100 may include a chamber body 102 having sidewalls 104, a base 106, and a lid 108 that may enclose a processing region 110. An injection apparatus 112 may be coupled with the sidewalls 104 and/or lid 108 of the chamber body 102. A gas panel 114 may be fluidly coupled with the injection apparatus 112 to allow process gases to be provided into the processing region 110. The injection apparatus 112 may be one or more nozzle or inlet ports, or alternatively a showerhead. Process gases, along with any processing by-products, may be removed from the processing region 110 through an exhaust port 116 formed in the sidewalls 104 or base 106 of the chamber body 102. The exhaust port 116 may be coupled with a pumping system 140, which may include throttle valves, pumps, or other materials utilized to control the vacuum levels within the processing region 110.

The process gases may be energized to form a plasma within the processing region 110. For example, the process gases may be energized by capacitively or inductively coupling RF power to the process gases. In the embodiment depicted in the figure, a plurality of coils 118 for inductively coupled plasma generation may be disposed above the lid 108 of the plasma processing chamber 100 and may be coupled through a matching circuit 120 to an RF power source 122.

The substrate support assembly 101 may be disposed in the processing region 110 below the injection apparatus 112. The substrate support assembly 101 may include an electrostatic chuck 103 and a base assembly 105. The base assembly may be coupled with the electrostatic chuck 103 and a facility plate 107. The facility plate 107 may be supported by a ground plate 111, and may be configured to facilitate electrical, cooling, heating, and gas connections with the substrate support assembly 101. The ground plate 111 may be supported by the base 106 of the processing chamber, although in some embodiments the assembly may couple with a shaft that may be vertically translatable within the processing region of the chamber. An insulator plate 109 may insulate the facility plate 107 from the ground plate 111, and may provide thermal and/or electrical insulation between the components.

The base assembly 105 may include or define a refrigerant channel coupled with a fluid delivery system 117. In some embodiments, fluid delivery system 117 may be a cryogenic chiller, although the present technology is not limited to cryogenic applications as will be explained further below. The fluid delivery system 117 may be in fluid communication with the refrigerant channel via a refrigerant inlet conduit 123 connected to an inlet of the refrigerant channel and via a refrigerant outlet conduit 125 connected to an outlet of the refrigerant channel such that the base assembly 105 may be maintained at a predetermined temperature, such as a first temperature. In some embodiments, the fluid delivery system 117 may be coupled with an interface box to control a flow rate of the refrigerant. The refrigerant may include a material that can maintain any temperature, including a cryogenic temperature, that may be below or about 0° C., below or about −50° C., below or about −80° C., below or about −100° C., below or about −125° C., below or about −150° C., or lower.

Again, it is to be understood that other substrate supports encompassed by the present technology may be configured to operate at a variety of other processing temperatures as well, including above or about 0° C., greater than or about 100° C., greater than or about 250° C., greater than or about 400° C., or greater. The fluid delivery system 117 may provide the refrigerant, which may be circulated through the refrigerant channel of the base assembly 105. The refrigerant flowing through the refrigerant channel may enable the base assembly 105 to be maintained at the processing temperature, which may assist in controlling the lateral temperature profile of the electrostatic chuck 103 so that a substrate 124 disposed on the electrostatic chuck 103 may be uniformly maintained at a cryogenic processing temperature.

The facility plate 107 may include or define a coolant channel coupled with a chiller 119. The chiller 119 may be in fluid communication with the coolant channel via a coolant inlet conduit 127 connected to an inlet of the coolant channel and via a coolant outlet conduit 129 connected to an outlet of the coolant channel such that the facility plate 107 may be maintained at a second temperature, which in some embodiments may be greater than the first temperature. In some embodiments, a single, common chiller may be used for fluid delivery to both the base assembly and the facility plate. Consequently, in some embodiments fluid delivery system 117 and chiller 119 may be a single chiller or fluid delivery system. In some embodiments, the chiller 119 may be coupled with an interface box to control a flow rate of the coolant. The coolant may include a material that can maintain temperatures greater than or about 0° C., and may maintain temperatures greater than or about 20° C., greater than or about 30° C., greater than or about 40° C., greater than or about 50° C., or greater. In some embodiments, alternative heating mechanisms may be employed including resistive heaters, which may be distributed in the facility plate, the electrostatic chuck, or the base assembly. In some embodiments the facility plate may not include heating components. The chiller 119 may provide the coolant, which may be circulated through the coolant channel of the facility plate 107. The coolant flowing through the coolant channel may enable the facility plate 107 to be maintained at a predetermined temperature, which may assist in maintaining the insulator plate 109 at a temperature above the first temperature, for example.

The electrostatic chuck 103 may include a support surface on which a substrate 124 may be disposed, and may also include a bottom surface 132 opposite the support surface. In some embodiments, the electrostatic chuck 103 may be or include a ceramic material, such as aluminum oxide, aluminum nitride, or other suitable materials. Additionally, the electrostatic chuck 103 may be or include a polymer, such as polyimide, polyetheretherketone, polyaryletherketone, or any other polymer which may operate as an electrostatic chuck within the processing chamber.

The electrostatic chuck 103 may include a chucking electrode 126 incorporated within the chuck body. The chucking electrode 126 may be configured as a monopole or bipolar electrode, or any other suitable arrangement for electrostatically clamping a substrate. The chucking electrode 126 may be coupled through an RF filter to a chucking power source 134, which may provide a DC power to electrostatically secure the substrate 124 to the support surface of the electrostatic chuck 103. The RF filter may prevent RF power utilized to form a plasma within the plasma processing chamber 100 from damaging electrical equipment or presenting an electrical hazard outside the chamber.

The electrostatic chuck 103 may include one or more resistive heaters 128 incorporated within the chuck body. The resistive heaters 128 may be utilized to elevate the temperature of the electrostatic chuck 103 to a processing temperature suitable for processing a substrate 124 disposed on the support surface. The resistive heaters 128 may be coupled through the facility plate 107 to a heater power source 136. The heater power source 136 may provide power, which may be several hundred watts or more, to the resistive heaters 128. The heater power source 136 may include a controller utilized to control the operation of the heater power source 136, which may generally be set to heat the substrate 124 to a predetermined processing temperature. In some embodiments, the resistive heaters 128 may include a plurality of laterally separated heating zones, and the controller may enable at least one zone of the resistive heaters 128 to be preferentially heated relative to the resistive heaters 128 located in one or more of the other zones. For example, the resistive heaters 128 may be arranged concentrically in a plurality of separated heating zones. The resistive heaters 128 may maintain the substrate 124 at a processing temperature suitable for processing.

The substrate support assembly 101 may include one or more probes disposed therein. In some embodiments, one or more low temperature optical probe assemblies may be coupled with a probe controller 138. Temperature probes may be disposed in the electrostatic chuck 103 to determine the temperature of various regions of the electrostatic chuck 103. In some embodiments, each probe may correspond to a zone of the plurality of laterally separated heating zones of the resistive heaters 128. The probes may measure the temperature of each zone of the electrostatic chuck 103. The probe controller 138 may be coupled with the heater power source 136 so that each zone of the resistive heaters 128 may be independently heated. This may allow the lateral temperature profile of the electrostatic chuck 103 to be maintained substantially uniform based on temperature measurements, which may allow a substrate 124 disposed on the electrostatic chuck 103 to be uniformly maintained at the processing temperature.

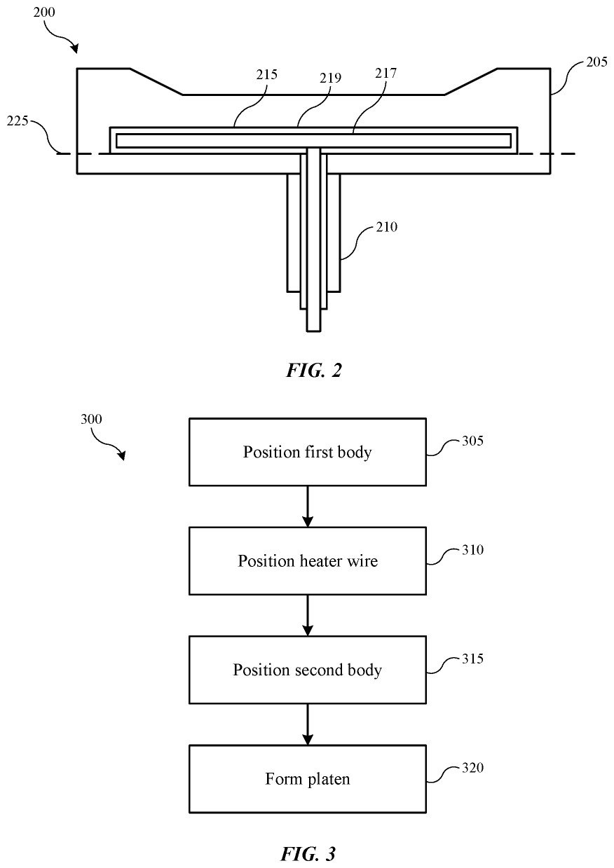

FIG. 2 shows a schematic partial cross-sectional view of an exemplary substrate support 200 according to some embodiments of the present technology. For example, substrate support 200 may illustrate a portion of substrate support assembly 101 described above, which may include any aspect of that support assembly, and may illustrate additional details of that support assembly. Substrate support 200 may illustrate a simplified cross-section of a support structure, which may include a number of other components or aspects as previously described, or as may be included in substrate supports. It is to be understood that substrate support 200 is not illustrated to any particular scale, and is included merely to illustrate aspects of the present technology. Substrate support 200 may be included within a chamber as previously described, as well as any other processing chamber, which may define a substrate processing region, such as with one or more walls of a chamber body, or other components positioned within the processing chamber.

Substrate support 200 may include a number of components bonded, welded, joined, sintered, formed or otherwise coupled with one another. Although a number of additional components may be included, as illustrated, the substrate support 200 may include a platen 205, which may include an electrode as previously described, and which may be coupled with a power source to provide electrostatic chucking or clamping of a substrate that may be seated on a surface of the puck. Any surface topography may be encompassed by the present technology, including a recessed pocket as illustrated, although in some embodiments platen 205 may define a number of protrusions or mesas on which a substrate may be seated. Similarly, a flat surface may also be formed for the platen 205. Platen 205 may be coupled with a stem 210, which may include one or more channels for fluid delivery, as well as access for component cables or coupling. Any of these components alone or together may constitute an electrostatic chuck assembly.

The platen 205 as well as the stem 210 may be or include a ceramic material or a polymeric material in some embodiments. Any number of ceramics, such as nitrides or oxides, may be used, as well as a range of polymeric materials, including polystyrene or other materials, including cross-linked materials. For example, in some embodiments the platen 205 may be aluminum nitride or aluminum oxide, although it is to be understood that any other materials may similarly be utilized, and various other combinations are similarly encompassed. Within platen may be a heater 215, which may be incorporated within or embedded within the platen 205. Heater 215 may be any number of heaters including fluid tubes or resistive heating elements. In some embodiments of the present technology, the heater 215 may be a metal wire and a barrier layer extending about the metal wire, although a barrier layer may similarly be formed about fluid tubes in some embodiments. Heater 215 may include a metal wire 217, which may be coated or covered with a barrier layer 219.

Metal wire 217 may be incorporated in any configuration including a coil, continuous rows, or any other configuration to provide heating throughout the platen 205. Metal wire 217 may have a body portion and a tail portion, which may extend from the platen into the stem 210, and may be coupled with a power source externally to the substrate support. In some embodiments, the tail portion may be coupled with the body portion, and in some embodiments, the tail portion may be continuous with the body portion to limit regions of different resistivity along the heater. Barrier layer 219 may similarly extend continuously along the metal wire 217, and may completely coat or be formed along the metal wire. Additionally, in some embodiments as illustrated, metal wire 217 may extend past the barrier layer 219 at an end external to the substrate support, and at a location where the metal wire 217 may be coupled with a power source.

Metal wire 217 may be or include any number of metals that may pass a current to resistively heat to a temperature for processing. The heater may transfer heat through the substrate support to a substrate for processing, and thus may be configured for providing heat uniformly through the substrate support. Additionally, metal wire 217 may be a material capable of withstanding a sintering process, which may occur under high temperature. Exemplary materials may be or include molybdenum, tungsten, platinum, tantalum, rhenium, nichrome, or any other materials that may operate as a resistive heater, and may be capable of withstanding high temperature formation processes. In some embodiments, the metal wire may be characterized by a diameter of less than or about 1 mm, and may be characterized by a diameter or thickness of less than or about 0.9 mm, less than or about 0.8 mm, less than or about 0.7 mm, less than or about 0.6 mm, less than or about 0.5 mm, less than or about 0.4 mm, less than or about 0.3 mm, less than or about 0.2 mm, less than or about 0.1 mm, or less. Heater 215 may be included in a heater in any location, and may be included between bodies prior to sintering. For example, line 225 may illustrate a location where previously a boundary between bodies existed prior to sintering where a monolith platen may be formed. Heater 215 may be disposed within either of two plates, or may be partially seated in each of two plates before sintering is performed.

As explained previously, during a sintering process, the metal wire may react or interact with components or impurities of the ceramic. For example, aluminum nitride powders utilized in forming green bodies may include a number of impurities, and the sintering process itself may occur in an oxygen-containing atmosphere. Sintering may be performed at temperatures well over 1,000° C., and exposure of the metal wire to these impurities may oxidize or convert a region of the metal wire. Even a very small area of affect can cause issues with heat uniformity. For example, as noted above, the wire or filament may be characterized by a thickness or diameter of less than or about 0.5 mm, such as about 0.2 mm or less. This may constitute a radius of 0.1 mm, and a cross sectional area of about 0.03 mm². Resistance along the heater wire may be calculated as the product of the electrical resistivity of the material and the length of the wire, divided by the area. Hence, because of the inverse relationship between resistance and area, as area decreases due to material oxidation or reaction, the resistance may increase.

Accordingly, even small conversions or oxidations on exterior surfaces of the filament may create regions of higher resistance, which may become hotter than surrounding areas when current is applied across the wire. Other reactions may produce regions on the metal wire characterized by lower electrical resistivity or higher resistivity, which may produce cold or hot spots when heated, with temperature differences of several degrees or more due to the differences in ressistance. For example, when a portion of the wire becomes oxidized, this region may become hotter, which may affect the surface temperature of the substrate support as well as the substrate. As many processes seek to maintain temperature uniformity on the range of one degree or less, these hot spots or cold spots may produce irregularities of deposited films or etched features.

The present technology may limit or prevent these occurrences by coating the metal wire with a barrier layer. The barrier layer may be any number of materials that may be able to coat or plate over the metal wire, may not interact or react with the metal wire, and may be able to withstand the sintering process without deformation or reaction. For example, in some embodiments the barrier layer may be an oxide or a nitride of a number of elements. For example, refractory metals and other metals, or oxides or nitrides of any number of metals may be used for the barrier layer.

Exemplary barrier layer materials may include aluminum, titanium, vanadium, chromium, manganese, zirconium, niobium, molybdenum, technetium, ruthenium, rhodium, hafnium, tantalum, tungsten, rhenium, osmium, or iridium, among any other material that may be characterized by a melting temperature greater than or about 1,500° C., greater than or about 1,600° C., greater than or about 1,700° C., greater than or about 1,800° C., greater than or about 1,900° C., greater than or about 2,000° C., greater than or about 2,100° C., or higher. The barrier layer of material may be formed by atomic layer deposition, or any other coating or plating technique, including electroplating. Consequently, in some embodiments the barrier layer may be characterized by a thickness of less than or about 100 μm, and may be characterized by a thickness of less than or about 50 μm, less than or about 30 μm, less than or about 20 μm, less than or about 10 μm, less than or about 8 μm, less than or about 6 μm, less than or about 5 μm, less than or about 4 μm, less than or about 3 μm, less than or about 2 μm, less than or about 1 μm, or less.

By incorporating barrier layers according to the present technology, metal wires included as resistive heaters may be characterized by a cross-sectional area that is consistent across the length of the wire within an error of less than or about 10%, and may be consistent within an error of less than or about 9%, less than or about 8%, less than or about 7%, less than or about 6%, less than or about 5%, less than or about 4%, less than or about 3%, less than or about 2%, less than or about 1%, less than or about 0.5%, less than or about 0.1%, or may be substantially or essentially consistent. Consequently, heaters utilizing the present technology may produce temperatures across a length of the heater that are also consistent within any of these noted ranges.

FIG. 3 illustrates selected operations in a method 300 of forming a semiconductor substrate support, which may be incorporated into any number of processing chambers, for example, in one or more chambers 100. Method 300 may include one or more operations prior to the initiation of the stated method operations, including formation of green bodies or molds, as well as formation of a barrier layer over a metal wire for use as a heater, or any other operations that may be performed prior to the described operations. The method may include a number of optional operations, which may or may not specifically be associated with the method according to the present technology. For example, many of the operations are described in order to provide a broader scope of the formation process, but are not critical to the technology, or may be performed by alternative methodology as will be discussed further below.

Method 300 may include forming a platen, which may be used as platen 205 as described above, and in which may be disposed or embedded a heater, which may have a metal wire and barrier layer as previously described. For example, at operation 305, a first body, such as a first ceramic body including a green body or powder material, may be placed within a mold or press for performing a sintering process. At operation 310, a heater may be disposed on or within a recess of the first body, or along a surface of the first body. The heater may include a metal wire and a barrier layer, which may include any of the materials or characteristics of any heater previously described.

At operation 315, a second body, such as a second ceramic body including a green body or powder material, may be placed within a mold or press for performing a sintering process. The second body may be placed overlying the first body and the heater. Either the first body or the second body may be or include any of the materials previously described. At operation 320, a monolith body may be formed by a sintering process. The sintering process may be performed at a temperature greater than or about 1,500° C., and may be performed at a temperature greater than or about 1,600° C., greater than or about 1,700° C., greater than or about 1,800° C., greater than or about 1,900° C., greater than or about 2,000° C., greater than or about 2,100° C., greater than or about 2,200° C., or higher. Subsequent the sintering process, the platen may be a single body incorporating the heater. By incorporating a barrier layer over the heater metal wire, interaction or reaction with impurities or oxygen associated with the process or materials may be limited or prevented. Accordingly, uniform temperatures may be produced by the heater, and improved temperature uniformity across a substrate support and substrate may be provided.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a layer” includes a plurality of such layers, and reference to “the probe” includes reference to one or more probes and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor substrate support comprising:
a platen configured to support a semiconductor substrate;
a stem coupled with the platen; and
a heater embedded within the platen, wherein the heater comprises a metal wire and a barrier layer extending about the metal wire.

2. The semiconductor substrate support of claim 1, wherein the platen comprises a ceramic.

3. The semiconductor substrate support of claim 1, wherein the metal wire comprises molybdenum or tungsten.

4. The semiconductor substrate support of claim 1, wherein the barrier layer comprises a nitride or oxide.

5. The semiconductor substrate support of claim 4, wherein the barrier layer comprises ruthenium, rhenium, or aluminum.

6. The semiconductor substrate support of claim 1, wherein the metal wire is characterized by a thickness of less than or about 0.5 mm.

7. The semiconductor substrate support of claim 1, wherein the barrier layer is characterized by a thickness of less than or about 10 μm.

8. A method of forming a semiconductor substrate support, the method comprising:
positioning a first body within a mold;
disposing a heater on the first body within the mold, wherein the heater comprises a metal wire and a barrier layer extending about the metal wire;
positioning a second body within the mold overlying the first body and the heater; and
forming a monolith body of the first body and the second body, wherein the monolith body comprises a platen for a semiconductor substrate support.

9. The method of forming a semiconductor substrate support of claim 8, wherein forming the monolith body comprises sintering the first body and the second body at a temperature greater than or about 1500° C.

10. The method of forming a semiconductor substrate support of claim 8, wherein the barrier layer comprises a nitride or oxide.

11. The method of forming a semiconductor substrate support of claim 8, wherein the barrier layer comprises ruthenium, rhenium, or aluminum.

12. The method of forming a semiconductor substrate support of claim 8, wherein the barrier layer prevents interaction between the metal wire and the first body or the second body.

13. The method of forming a semiconductor substrate support of claim 8, wherein the metal wire is characterized by a thickness of less than or about 0.3 mm.

14. The method of forming a semiconductor substrate support of claim 8, wherein the barrier layer is characterized by a thickness of less than or about 5 μm.

15. The method of forming a semiconductor substrate support of claim 8, wherein the platen comprises a ceramic.

16. The method of forming a semiconductor substrate support of claim 15, wherein the ceramic comprises aluminum oxide or aluminum nitride.

17. The method of forming a semiconductor substrate support of claim 8, wherein the metal wire comprises molybdenum or tungsten.

18. A method of forming a semiconductor substrate support, the method comprising:
positioning a first ceramic body within a mold;
disposing a heater on the first ceramic body within the mold, wherein the heater comprises a molybdenum or tungsten wire and an oxide or nitride barrier layer extending about the molybdenum or tungsten wire;
positioning a second ceramic body within the mold overlying the first ceramic body and the heater; and
sintering the first ceramic body and the second ceramic body to form a monolith body platen of a semiconductor substrate support.

19. The method of forming a semiconductor substrate support of claim 18, wherein forming the monolith body platen comprises sintering the first ceramic body and the second ceramic body at a temperature greater than or about 1700° C.

20. The method of forming a semiconductor substrate support of claim 18, wherein the molybdenum or tungsten wire is characterized by a thickness of less than or about 0.3 mm, and wherein the oxide or nitride barrier layer is characterized by a thickness of less than or about 5 μm.
